(19) United States
(12) Patent Application Publication
(10) Pub. No.: US 2014/0261666 A1
(43) Pub. Date: Sep. 18, 2014

(54) METHODS OF MANUFACTURING A LOW COST SOLAR CELL DEVICE

(71) Applicant: Applied Materials, Inc., Santa Clara, CA (US)

(72) Inventors: Michael P. STEWART, San Francisco, CA (US); Prabhat KUMAR, Fremont, CA (US)

(73) Assignee: APPLIED MATERIALS, INC., Santa Clara, CA (US)

(21) Appl. No.: 14/209,425

(22) Filed: Mar. 13, 2014

Related U.S. Application Data
(60) Provisional application No. 61/780,820, filed on Mar. 13, 2013.

(51) Int. Cl. H01L 31/0236; H01L 31/0224

(52) U.S. Cl. CPC H01L 31/02366; H01L 31/022425
USPC 136/256; 438/98

(57) ABSTRACT

Embodiments of the present invention are directed to processes for making solar cells by simultaneously co-firing metal layers disposed both on a first and a second surface of a bifacial solar cell substrate. Embodiments of the invention may also provide a method forming a solar cell structure that utilize a reduced amount of a silver paste on a front surface of the solar cell substrate and a patterned aluminum metallization paste on a rear surface of the solar cell substrate to form a rear surface contact structure. Embodiments can be used to form passivated emitter and rear cells (PERC), passivated emitter rear locally diffused solar cells (PERL), passivated emitter, rear totally-diffused (PERT), “iPERC,” Crystalline Reduced-cost Aluminum Fire-Through (CRAFT), pCRAFT, nCRAFT or other high efficiency cell concepts.

### CROSS-REFERENCE TO RELATED APPLICATIONS

This application claims benefit of U.S. provisional patent application Ser. No. 61/780,820, filed Mar. 13, 2013, which is hereby incorporated herein by reference.

### BACKGROUND OF THE INVENTION

1. Field of the Invention

Embodiments of the present invention generally relate to a process for forming crystalline solar cells.

2. Description of the Related Art

Solar cells are photovoltaic devices that convert sunlight directly into electrical power. The most common solar cell material is silicon, which is in the form of single or multicrystalline substrates, sometimes referred to as wafers. Because the amortized cost of forming silicon-based solar cells to generate electricity is higher than the cost of generating electricity using traditional methods, there has been an effort to reduce the cost required to form solar cells.

FIG. 1 depicts a cross sectional view of a conventional crystalline silicon type solar cell substrate, or substrate 110 that may have a passivation layer 104 formed on a surface, e.g. a back surface 125, of the substrate 110. A silicon solar cell 100 is fabricated on the crystalline silicon type solar cell substrate 110 having a textured surface 112. The substrate 110 typically includes a p-type base region 121, an n-type emitter region 122, and a p-n junction region 123 disposed therebetween. The p-n junction region 123 is formed between the p-type base region 121 and the n-type emitter region 122 to form a solar cell 100. An electrical current flows within the solar cell when light strikes a front surface 120 of the solar cell 100. The generated electrical current flows through metal front contacts 108 and metal back contacts 106 formed on a back surface 125 of the substrate 110.

A passivation layer 104 may be disposed between the back contact 106 and the p-type base region 121 on the back surface 125 of the solar cell 100. The passivation layer 104 may be a dielectric layer providing good interface properties which can reduce the recombination of the electrons and holes, drive and/or diffuse electrons and charge carriers back to the junction region 123, and minimize light absorption. The passivation layer 104 is drilled and/or patterned to form openings 109 (e.g., back contact through-holes) that allow regions 107 of the back contact 106 to extend through the passivation layer 104 to be in electrical contact/communication with the p-type base region 121. The regions 107 may be formed through the passivation layer 104 so that they are electrically connected to the back contact 106 to facilitate electrical flow between the back contact 106 and the p-type base region 121. Generally, the back contact 106 is formed on the passivation layer 104 by a flood printing metal paste process, and pasting metal into the openings 109 formed in the passivation layer 104. The typical flood printed or blanket deposited aluminum (Al) layer, which is used to form the rear electrical back contact 106, covers most if not the entire rear surface of the substrate 121. Due to benefits gained by use of a simplified manufacturing process, which include the elimination of the need to align the flood printed material with the formed openings 109, the flood printed back contact 106 typically includes an excessive amount of the expensive flood printed paste material to perform the task of collecting and carrying the generated current from the rear surface of the solar cell to the module interconnect. The terms “back” and “rear” are used herein interchangeably to describe surfaces, contacts, and other features of solar cells on the back side of substrates.

There are various approaches for fabricating the active regions and the current carrying metal lines, or conductors, of the solar cells. Manufacturing high efficiency solar cells at low cost is the key for making solar cells more competitive for the generation of electricity for mass consumption. The efficiency of solar cells is directly related to the ability of a cell to collect charges generated from absorbed photons in the various layers. A good passivation layer can provide a desired film property that reduces recombination of the electrons or holes in the solar cells and redirects electrons and charges back into the solar cells to generate photocurrent. When electrons and holes recombine, the incident solar energy is re-emitted as heat or light, thereby lowering the conversion efficiency of the solar cells.

In an effort to improve solar cell efficiency, bifacial solar cells have been developed. Generally, it is advantageous to have solar cells which collect as much light as possible in order to generate more electric current. Bifacial solar cells are different from conventional (single-sided) solar cells, since they allow light to be received from both the front and rear surfaces of the solar cell substrate. A bifacial solar cell can receive light reflected from reflective components, such as a mirror or white roof surface, positioned near the back of the solar cell substrate, thus the amount of energy that can be provided per bifacial cell in a solar cell module can be increased over conventional solar cells.

Therefore, there exists a need for an improved method and apparatus for manufacturing bifacial solar cell devices that have a desirable device performance as well as a low manufacturing cost.

### SUMMARY OF THE INVENTION

Embodiments of the present disclosure may provide a method of manufacturing a solar cell device, comprising forming a doped region on a first surface of a substrate, forming a first dielectric layer on the first surface of the substrate, forming a second dielectric layer on a second surface of the substrate, depositing a first metal paste in a first pattern on at least a portion of the first dielectric layer, depositing a second metal paste in a second pattern on the second dielectric layer, wherein the second dielectric layer is disposed between the portions of the second metal paste and the second surface of the substrate, and the second metal paste comprises aluminum, and simultaneously heating the first and the second metal pastes disposed on the first and the second dielectric layers to form a first group of contacts to the substrate through portions of the first dielectric layer and a second group of contacts to the substrate through the second dielectric layer, wherein at least a portion of the second metal paste forms a plurality of contact regions that each extend through the second dielectric layer from the surface of the second dielectric layer to the second side of the substrate.

Embodiments of the present invention may provide a bifacial solar cell device, comprising a substrate having a first dielectric layer disposed on a first side of the substrate and a second dielectric layer disposed on a second side of the substrate, wherein the first side of the substrate includes a textured surface, a first metal layer that is formed in a first pattern on the first side of the substrate, and a second metal layer that is formed in a second pattern on the second side of the substrate, wherein the second metal comprises aluminum and the second dielectric layer comprises aluminum oxide, silicon oxide, silicon oxynitride, aluminum silicon oxide, aluminum oxynitride, aluminum silicon oxynitride, and dielectric stacks, such as AlOₓ/SiN_{y}, SiO₂/SiNₓ, SiOₓN_{y}/SiN_{z}.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1 illustrates a cross-sectional view of a conventional solar cell substrate;

FIGS. 2A-2B illustrate cross-sectional views of a solar cell substrate according to another embodiment of the invention;

FIG. 2C illustrates a front view of a solar cell substrate according to an embodiment of the invention;

FIG. 2D illustrates a rear view of a solar cell substrate according to an embodiment of the invention;

FIG. 3 depicts a cross-sectional view of a solar cell substrate.

FIGS. 4A-4T depict cross-sectional views of a solar cell substrate during different stages of a processing sequence illustrated in FIGS. 5A-5B according to one embodiment of the invention;

FIG. 5A depicts a block diagram of a processing sequence used to form solar cell devices in accordance with one embodiment of the present disclosure;

FIG. 5B depicts a block diagram of a processing sequence used to form solar cell devices in accordance with one embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation. The drawings referred to here should not be understood as being drawn to scale unless specifically noted. Also, the drawings are often simplified and details or components omitted for clarity of presentation and explanation. The drawings and discussion serve to explain principles discussed below, where like designations denote like elements.

### DETAILED DESCRIPTION

Embodiments of the present invention are directed to processes for making solar cells. Particularly, embodiments of the invention provide simultaneously co-firing (e.g., thermally processing) metal-containing layers disposed both on a first and a second surface of a bifacial solar cell substrate to complete the metallization process in one step. By doing so, the metal layers formed on the first and the second surfaces of the solar cell substrate are co-fired (e.g., simultaneously thermally processed), thereby eliminating manufacturing complexity, cycle time and cost to produce the solar cell device. Embodiments of the invention may also provide a method forming a solar cell structure that utilizes a reduced amount of a silver paste on a front surface of the solar cell substrate and a reduced amount of aluminum metallization paste on a rear surface of the solar cell substrate to form contact structures on the front and rear surfaces. The methods described herein can be used to reduce the manufacturing cost and increase the power output from a formed bifacial solar cell device. Embodiments can be used to form “passivated emitter and rear cells” (PERC), “Passivated Emitter Rear Locally Diffused Solar Cells” (PERL), “passivated emitter, rear totally-diffused” (PERT), “iPERC”, Crystalline Reduced-cost Aluminum Fire-Through (CRAFT), pCRAFT, nCRAFT or other high efficiency cell concepts. The methods described herein are especially useful for forming CRAFT, PERL, PERC or PERT bifacial types of solar cells. In one example, a bifacial solar cell, whose front and rear surfaces are each connected to a patterned metallic layer, may have a boosted power generation of up to 25% and have a 40% lower manufacturing cost.

One skilled in the art will appreciate that as the manufacturing cost of the solar cell substrate, which is typically the largest portion of a crystalline solar cell manufacturing cost, decreases, the cost of the other materials used to form a solar cell device becomes a larger portion of the solar cell's total manufacturing cost. It has been found that conventional “flood printing,” or blanket metal paste layer deposition across large portions of the rear surface of the substrate, accounts for a significant portion of the total cost of forming a conventional solar cell device. Moreover, conventional flood printed or blanket deposited metal layers that are formed on the rear surface of the solar cell prevent any light that impinges on the rear surface from making it to the active region of the solar cell (e.g., p-n junction), and thus blanket metal layers are not useful for forming a bifacial solar cell.

Embodiments of the invention disclosed herein thus propose a method of reducing the amount and/or type of metal paste used to form the rear contact structure on a solar cell device, reduce the number of processing steps required to form a solar cell device and reduce the solar cell fabrication process sequence complexity. In one example, the methods described herein reduce the process sequence complexity by eliminating the need to form vias in the rear surface passivation layer to enable an electrical contact to be formed between the solar cell substrate and the rear contact structure, by eliminating the need for any subsequent cleaning processes used to prepare the substrate surface for the contact metallization processes, and by eliminating the need for contact metallization alignment steps required to align the metal material in the front and/or rear contact structures with the vias. The methods described herein can also reduce the amount of metal paste used to form a bifacial solar cell device by between about 60% and 99.6% over a conventional blanket deposited metal paste layer containing solar cell device. The reduced consumption of metal paste, reduced number of process steps, and increased bifacial light collection can decrease the effective production cost per peak watt ($/Wp) by 30-50%. The production cost per peak watt ($/Wp) is typically different than the operation cost per watt, which is typically quoted by solar cell installation companies.

Embodiments of the invention provide simultaneously co-firing (e.g., thermally processing) metal layers disposed both on a first and a second surface of a solar cell substrate to complete the metallization process in one step. By doing so, both the metal layers formed on the first and the second surfaces of the solar cell substrate are co-fired (e.g., simultaneously thermally processed), thereby eliminating manufacturing complexity, cycle time and cost to produce the solar cell device. Embodiments of the invention may also provide a method and solar cell structure that requires a reduced amount of a metallization paste on a rear surface of the substrate to form a rear surface contact structure and, thus, reduce the cost of the formed solar cell device.

FIG. 2A depicts a cross sectional view of a bifacial solar cell 200, according to one embodiment of the invention. The bifacial solar cell 200 is a PERL type bifacial solar cell that is configured to receive electromagnetic energy E from the sun on a front surface 204 and electromagnetic energy E′ reflected from an external reflector 190 on a rear surface 206 of a solar cell substrate 202. The bifacial solar cell 200 may include a passivation layer 218 formed over an emitter region 241 formed on the front surface 204 and a passivation layer 220 formed on the back surface 206 of the substrate 202, according to one embodiment of the invention. In one example, the passivation layer 218 includes a multilayer stack of dielectric films 218A, 218B that are used to form an ARC layer and passivate the front surface 204 of the solar cell substrate 202. A bifacial solar cell 200 may be fabricated on a crystalline silicon type solar cell substrate 202 that has a textured front surface, such as surface 204 shown in FIG. 2A. While FIG. 2A also illustrates a bifacial solar cell 200 that also has a rear surface 206 that is textured, this configuration is not intended to be limiting to the scope of the invention described herein. In one example, the substrate 202 includes a p-type base region, an n-type emitter region 241, and a p-n junction region disposed therebetween. In another example, the n-type emitter region 241 includes an n⁺ doped region that is formed in a p-type doped solar cell substrate, or alternately a p⁺ doped region that is formed in an n-type doped solar cell substrate 202. In some configurations, a “reverse”-type solar cell may be used that includes a substrate 202 that has an n-type doped solar cell substrate, an emitter region 241 that includes an n⁺ doped region, and p-type regions that are formed by the diffusion of a p-type material found in the rear contact structure 222 (e.g., aluminum paste material that is used to form the rear surface contact region 232) into the substrate. The bifacial solar cell 200 also includes a front contact structure 226 and a rear contact structure 222 that have desired cross-sectional areas to carry a desired amount of the generated current and are formed in desired patterns to assure that a large portion of the electromagnetic energy E, E′ is received by the exposed regions (e.g., regions not covered by the front contact structure 226 and the rear contact structure 222) of the front surface 204 and rear surface 206 of the substrate 202 in the bifacial solar cell 200.

FIG. 2B depicts an alternate configuration of the bifacial solar cell 200, according to one embodiment of the invention. The bifacial solar cell 200, as illustrated in FIG. 2B, includes a PERT type bifacial solar cell that is configured to receive electromagnetic energy E from the sun on a front surface 204 and electromagnetic energy E′ reflected from a reflector 190 on a rear surface 206 of a solar cell substrate 202. The bifacial solar cell 200 illustrated in FIG. 2B contains similar elements as the bifacial solar cell illustrated in FIG. 2A, except that a rear diffused region 242 is additionally formed within the rear surface 206 of the substrate 202 to form the PERT type solar cell. The rear diffused region 242 includes a doped region that is doped with an element that is similar to the dopant found within the solar cell substrate 202. In one example, the rear diffused region 242 includes a p⁺ doped region that is formed in a p-type doped solar cell substrate, or an n⁺ doped region that is formed in an n-type doped solar cell substrate. Since the bifacial solar cells 200 illustrated in FIGS. 2A and 2B contain similar elements, like reference numerals have been used to label these components, and thus these reference numerals are not re-discussed herein.

FIG. 2C is an isometric view of the front surface 204 of the solar cell substrate 202 that has the front contact structure 226 formed thereon. The front contact structure 226 may include busbars 226A and fingers 226B, that are sized to efficiently transfer the generated current received at the front surface 204 of the solar cell 200, and minimally block the electromagnetic energy E received at the front surface 204 of the solar cell substrate 202. In one example, the front contact structure 226 includes a silver containing material that is formed from a metallic paste that contains silver (Ag) particles. In one example, the front contact structure 226 covers less than about 10% of the front surface 204. In another example, the exposed surface area of the front surface 204 remaining after depositing the front contact structure 226 is between about 98% and about 94%.

FIG. 2D is an isometric view of the rear surface 206 of the substrate 202 that has the rear contact structure 222 formed thereon. The rear contact structure 222 may include busbars 222A (Y-direction) and fingers 222B (X-direction), that are sized to effectively transfer the generated current received at the rear surface 206 of the solar cell 200, and minimally block the reflected electromagnetic energy E′ received at the rear surface 206 of the solar cell substrate 202. In one example, the rear contact structure 222 covers less than about 30% of the rear surface 206. In another example, the exposed surface area of the rear surface 206 remaining after depositing the rear contact structure 222 is between about 90% and about 70% of the rear surface 206. In one configuration, the rear contract structure 222 is formed in a similar geometric pattern on the rear surface 206 as the front contact structure 226 is formed on the front surface 204, but contains between about 50% and about 200% more volume of material to account for differences in the way the materials in each contact structure sinter during the co-firing process (step 520 of FIG. 5) and differences in their electrical conductivity. In one configuration, the geometric pattern of the deposited material in the front contact structure 226 is the same as the geometric pattern of the deposited material in the rear contact structure 222.

In one embodiment, the rear contact structure 222 is formed using an aluminum (Al) paste, which contains aluminum particles disposed therein, to form electrical contacts and back-surface-field (BSF) regions on the rear surface of a p-type substrate. In one embodiment, the aluminum paste is selected to facilitate the low temperature dissolution of an aluminum oxide, found in the passivation layer 220, and the formation of aluminum silicon alloys during a metal contact co-firing process, which will be discussed below in detail. In some embodiments, the current carrying cross-sectional area of the busbars 222A and/or fingers 222B in the rear contact structure 222 is greater than or equal to the corresponding current carrying cross-sectional area of each of the busbars 226A and/or fingers 226B in the front contact structure 226.

In another embodiment, as illustrated in FIG. 3, the rear contact structure 222 is formed using an aluminum (Al) paste, which contains aluminum particles disposed therein, to form electrical contacts to the rear surface of a p-type substrate that already has a rear-side diffused or implanted p+ layer, such as a boron BSF (layer 242), disposed therein. In this embodiment, the aluminum paste is selected to facilitate the low temperature dissolution of an aluminum oxide, found in the passivation layer 220, and consequently the formation of an ohmic contact to the p⁺ layer on the wafer. Due to the presence of a p⁺ layer, the aluminum (Al) can function as a contacting layer and not a p-type doping source for a BSF. Alternately, the fired aluminum (Al) may form concentrated regions of dopant in the BSF, creating selective p⁺⁺ or higher concentration p⁺ regions at the fire-though points (209A). In some embodiments, the current carrying cross-sectional area of the busbars 222A and/or fingers 222B in the rear contact structure 222 is greater than or equal to the current carrying cross-sectional area of each of the corresponding busbars 226A and/or fingers 226B in the front contact structure 226.

### Process Sequence Examples

FIGS. 4A-4T depict cross-sectional views of a solar cell substrate during different stages of a processing sequence illustrated in FIGS. 5A-5B according to one embodiment of the invention. FIGS. 5A-5B are block diagrams of a processing sequence 500 used to form a solar cell device in accordance with one embodiment of the present invention. It is noted that the processing sequences depicted in FIGS. 4A-4T and 5A-5B are only used as an example of a process flow that can be used to manufacture a solar cell device. Additional steps may be added in between the steps depicted in FIG. 5A-5B as needed to form a desirable solar cell device. Similarly, some steps depicted herein may also be eliminated as needed. It is contemplated that one or more metal or dielectric layers formed on a front or a back side of a substrate may be formed at any desired stage as needed.

In the embodiment, as depicted in FIGS. 4A and 5A, the process starts at step 502 by providing a substrate 202 having a p-type or n-type dopant disposed in one or more surfaces of the substrate 202. The substrate 202 may be a single crystal or multicrystalline silicon substrate, silicon containing substrate, fully doped silicon containing substrate, or other suitable substrates. In one embodiment, the substrate 202 is a doped silicon containing substrate with either p-type dopants or n-type dopants disposed therein. In one configuration, the substrate 202 is a p-type crystalline silicon (c-Si) substrate. P-type dopants used in silicon solar cell manufacturing are chemical elements, such as, boron (B), aluminum (Al) or gallium (Ga). In another configuration, the crystalline silicon substrate 202 may be an electronic grade silicon substrate or a low lifetime, defect-rich silicon substrate, for example, an upgraded metallurgical grade (UMG) crystalline silicon substrate. The upgraded metallurgical grade (UMG) silicon is a relatively clean polysilicon material having a low concentration of heavy metals and other undesirable impurities, for example in the parts per million range, but which may contain a high concentration of boron or phosphorus, depending on the source. In certain applications, the substrate can be a back-contact silicon substrate prepared by emitter wrap through (EWT), metallization wrap around (MWA), or metallization wrap through (MWT) approaches. Although the embodiment depicted herein and relevant discussion thereof primarily discuss the use of a p-type c-Si substrate, this configuration is not intended to be limiting as to the scope of the invention, since an n-type c-Si substrate may also be used without deviating from the basic scope of the embodiments of the invention described herein. The doping layers or emitters formed over the substrate will vary based on the type of substrate that is used, as will be discussed below.

At step 504, the substrate 202 is cleaned and textured. During the cleaning process, undesirable material is removed from surfaces 204, 206 of the substrate 202 and then the texturing process at least roughens the first surface 204 of the substrate 202 to form at least a textured surface 208 on the first surface 204, as shown in FIG. 4B. The textured surface 208 on the front side of the solar cell substrate 202 is adapted to receive sunlight after the solar cell has been formed. The textured surface 208 is formed to enhance light trapping in the solar cells to improve conversion efficiency. The substrate 202 generally has the first surface 204 (e.g., a front surface) and the second surface 206 (e.g., a back surface or rear surface), which is generally opposite to the first surface 204 and on the opposite side of the substrate 202. The substrate 202 may be cleaned using a wet cleaning process in which it is sprayed with a cleaning solution. The cleaning solution may be any conventional cleaning solution, such as HF-last type cleaning solution, ozonated water cleaning solution, hydrofluoric acid (HF) and hydrogen peroxide (H₂O₂) solution, or other suitable cleaning solution. The cleaning process may be performed on the substrate 202 for between about 5 seconds and about 600 seconds, such as about 320 seconds.

The rear surface 206 of the substrate 202 may also be textured during the texturing process as well to form a textured surface 209, as shown in FIG. 4B. In one example, the textured surfaces 208 and/or 209 are formed on the substrate 202 by use of an etching solution comprising between about 2.7% by volume of potassium hydroxide (KOH) and about 4500 ppm of 300 MW PEG that is maintained at a temperature of about 79-80° C. for about 30 minutes. In one embodiment, the etching solution for etching a silicon substrate may be an aqueous potassium hydroxide (KOH), sodium hydroxide (NaOH), aqueous ammonia (NH₄OH), tetramethylammonium hydroxide (TMAH; or (CH₃)₄NOH), or other similar basic solution. The etching solution will generally anisotropically etch the substrate 202, forming pyramids on the textured surfaces 208 and 209 of the substrate 202.

In some embodiments, before proceeding on to step 506 or to step 507, a rear surface polishing step 505 (see FIG. 4C) is optionally performed to reduce or eliminate the surface texture formed on the rear surface 206 of the substrate 202 so that a relatively flat and stable rear surface 206 can be formed. The rear surface polishing process may be performed using a chemical mechanical polishing (CMP) process or other similar method that can remove the surface roughness created during the texturing process. In some embodiments of the invention, the rear surface polishing process is completed after performing one or more of the following process steps, such as after reaching point 512 in the processing sequence 500. While the portion of the processing sequence 500 that contains steps 507, 509 and 511, as illustrated in FIGS. 4D-4F and their subsequent processing steps, have a rear polished surface, these processing steps generally do not require the surface 206 to be polished, and are illustrated this way to provide an example of how this rear surface configuration differs from a non-polished version of the rear surface 206 as FIGS. 4I-4J.

### Diffusion Sequence Processing Steps

At step 506, as shown in FIG. 4I, a dopant material, such as a doping gas, is used to form a doped region 213 (e.g., p⁺ or n⁺ doped region) on one or more of the surfaces of the solar cell substrate 202. The doped region 213 may be used to form at least a portion of the emitter region 241 illustrated in FIGS. 2A-2B. In one embodiment, the doped region 213 is formed in the substrate 202 by use of a gas phase doping process. In some cases, the doped region 213 may be predominantly formed on the exposed surfaces of the solar cell substrate 202 and only minimally on any masked or supported surfaces (e.g., back surface 206 in FIG. 4I). In one embodiment, the doped region 213 is between about 50 Å and about 20 μm thick and comprises an n-type or p-type dopant atom.

In one embodiment, the doped region 213 may be an n-type dopant that is disposed in a p-type substrate 202. In one example, phosphorus (P) dopant atoms from the doping gas are doped into the front surface 204 of the substrate 202 by use of a phosphorous oxychloride (POCl₃) diffusion process that is performed at a relatively high processing temperature. In one example, the substrate 202 is heated to a temperature greater than about 800° C. in the presence of a dopant containing gas to causes the doping elements in the dopant containing gas to diffuse into the surfaces of the substrate to form a doped region. In one embodiment, the substrate is heated to a temperature between about 800° C. and about 1300° C. in the presence of phosphorus oxychloride (POCl₃) containing gas for between about 1 and about 120 minutes. Other examples of dopant materials may include, but are not limited to polyphosphoric acid, phosphosilicate glass precursors, phosphoric acid (H₃PO₄), phosphorus acid (H₃PO₃), hypophosphorous acid (H₃PO₂), and/or various ammonium salts thereof.

In embodiments where the substrate 202 is an n-type substrate, the doped region 213 may be formed using a p-type dopant material, such as boric acid (H₃BO₃). The processes performed during step 506 may be performed by any suitable heat treatment module. In one embodiment, the heat treatment module is a rapid thermal annealing (RTA) chamber, annealing chamber, a tube furnace or belt furnace chamber.

In an alternate embodiment of step 506, the doped region 213 may be formed by depositing or printing a dopant material in a desired pattern on one or more surfaces of the substrate 202 by screen printing, ink jet printing, spray deposition, rubber stamping, laser diffusion or other similar processes, followed by driving the dopant atoms of the dopant material into the surface(s) of the substrate. The dopant source material may initially be a liquid, paste, or gel that is used to form heavily doped regions 213 in the substrate 202. The substrate 202 is then heated to a temperature greater than about 800° C. to cause the dopants to drive-in or diffuse into the surface of the substrate 202 to form the doped region 213 shown in FIG. 4I. In one embodiment, the drive-in process is performed by heating the substrate 202 to a temperature between about 800° C. and about 1300° C. for a desired period of time, for example, about 1 minute to 120 minutes. The drive-in process may be performed by any suitable heat treatment module, such as a rapid thermal anneal module.

After the forming the doped region 213, the substrate 202 may be gradually cooled to a desired temperature. The temperature of the substrate 202 may be ramped down at a ramp-down rate between about 5° C./second and about 350° C./second from the diffusion temperature of about 850° C. to a desired temperature of about 700° C. or less, such as about room temperature.

In one embodiment of step 506, the doped region 213 is formed on all of the surfaces of the substrate using a one or more of the doping processes described above. After forming a doped region on all surfaces, it is often desirable to remove a portion of the doped region from at least one surface of the substrate 202, so that electrical contacts can be formed directly with the p-type and n-type regions of the formed solar cell. An etching process, such as the one discussed below in conjunction with step 508, can be used to remove at least a portion of the doped region 213 from at least one surface of the substrate.

In some embodiments where it is desirable to form a PERT solar cell, it is desirable to dope opposing sides of a substrate with different dopant types. In one example, a p-type solar cell substrate may have an n-type doped region 213 formed on the front surface 204 and a p-type doped region formed on the rear surface 206 of the substrate. In another example, an n-type solar cell substrate may have an p-type doped region 213 formed on the front surface 204 and an n-type doped region formed on the rear surface 206 of the substrate. The process(es) used to form the different doped regions on different surfaces of the substrate may include masking steps and two different dopant type diffusion steps, use of a different implant process on each surface, or other similar doping technique. In one configuration of the processing sequence 500, step 506 is performed a first time to cause a first dopant to be driven into a first surface of the substrate (e.g., n-type dopant into the front surface 204), then a masking step is performed to cover the exposed regions of a first surface, and then step 506 is performed a second time so that a second dopant is driven into a second surface of the substrate (e.g., p-type dopant into the rear surface 206). In some configurations, it is desirable to perform step 509 (e.g., oxidation anneal step), which is discussed below, after performing step 506 and prior to continuing on to step 508 below.

At step 508, as illustrated in FIG. 4J, an etching and/or isolation cleaning process may be optionally performed on the substrate 202 to remove any undesirable residues or oxides, such as phosphosilicate glass (PSG) layers, formed during step 506 or other previous processing steps, from the substrate 202. The substrate 202 may be cleaned using a wet cleaning process in which it is sprayed with a cleaning solution. The cleaning solution may include a hydrofluoric acid (HF) and nitric acid (HNO₃) chemistry, an HF and acetic acid chemistry, an HF and sulfuric acid (H₂SO₄) chemistry, or include any conventional cleaning solution, such as an HF-last type cleaning solution, ozonated water cleaning solution, hydrofluoric acid (HF) and hydrogen peroxide (H₂O₂) solution, or other suitable cleaning solution. The cleaning process may be performed on the substrate 202 for between about 5 seconds and about 600 seconds, such as about 320 seconds. The step 508 process(es) may also be performed in a similar fashion discussed above with respect to step 504. In some embodiments, as noted above, step 508 may include a processing step in which the doped region 213 or portion of the doped region 213 is removed from a surface of the substrate 202. In one example, the etching process may comprise applying a wet chemistry to the rear surface to selectively remove the doped region 213.

In one example of step 508, an isotropic etching process may be performed on one or more surfaces of the substrate 202 for between about 5 seconds and about 600 seconds, such as about 30 seconds to about 240 seconds. Alternately, the etching process may be a dry etching process such as an isotropic etching, a remote or direct plasma from NF₃, SF₆, F₂, NCl₃, Cl₂, or a vapor comprising HF and O₃, combinations thereof or other suitable gas species, to remove undesired contaminants and residuals from the surfaces of the substrate 202 as needed.

### Implant Sequence Processing Steps

In one embodiment of the processing sequence 500, instead of performing steps 506 and 508 to form the junction regions of the bifacial solar cell, an alternate bifacial cell formation process is used. In one example, the alternate bifacial solar cell processing sequence includes at least one of the processing steps 507, 509 and 511, which are discussed below.

At step 507, as illustrated in FIG. 4D, one or more doped regions 213 are formed in one or more of the surfaces 206 and/or 204 of the substrate 202 by use of an implant process. In one embodiment, an implant process is used to form part of a PERL or a PERC type of solar cell by forming an n-type doped region in the front surface 204 of a p-type substrate 202, or form a p-type doped region in the front surface 204 of an n-type substrate 202. In another embodiment, an implant process is used to form part of a PERT type of solar cell by forming an n-type doped region in the front surface 204, and a more heavily doped p-type region in the rear surface 206 of a p-type substrate 202. In an alternate embodiment, an implant process is used to form part of a PERT type of solar cell by forming a p-type doped region in the front surface 204, and a more heavily doped n-type doped region 213 in the rear surface 206 of an n-type the substrate 202. In one method, the substrate 202 is doped prior to performing an oxidation (step 509). The implant process performed in step 507 may use an implant energy of between about 5 keV and about 15 keV, to achieve a depth of between about 200 and about 1000 nm, and a 10¹⁴ to 10¹⁹ cm⁻³ initial implanted dose depending on the type of dopant used. The implant step 507 may be performed by use of a plasma doping, plasma immersion, or beam-line ion implanter. Step 507 may be performed in a cluster tool configuration that includes pre-treatments or post-treatments in a sequence.

At step 509, an oxidation anneal step is performed on the surface 202 after performing step 507 so that an oxide layer 214 is formed on the surfaces of the substrate 202, as illustrated in FIG. 4E. In one embodiment of the process(es) performed at step 509, the substrate is heated to a temperature between about 750° C. and about 1300° C. in the presence of nitrogen (N₂), oxygen (O₂), oxygen radicals, hydrogen (H₂), air, ozone (O₃), water vapor or combinations thereof for between about 1 minute and about 120 minutes. In one example, the substrate is heated in a rapid thermal annealing (RTA) chamber in an oxygen rich and/or nitrogen (N₂) rich environment to a temperature of about 1000° C. for about 5 minutes. The process described in step 509 may be performed by a heat treatment module that is positioned within the solar cell production line. In one embodiment, the heat treatment module is a rapid thermal annealing (RTA) chamber such as a Vantage Radiance Plus™ RTP chamber available from Applied Materials Inc. of Santa Clara, Calif. Other processing chambers such as an annealing chamber, a tube furnace or belt furnace chamber may also be used to practice the present invention. In one embodiment, the second deposition processing module is a processing chamber contained in a processing module disposed within a SoftLine™ tool available from Baccini S.p.A, which is a division of Applied Materials Inc. of Santa Clara, Calif. A dopant, which has a negative segregation coefficient in the formed oxide layer, will segregate from the doped region 213 to a region within the oxide layer 214. The dose of these species may be chosen based on the amount of dopant that segregates in the formed oxide. A dopant gradient in region 213 results from the preferential segregation of dopants into the oxide during its growth.

At step 511, the substrate 202 is optionally cleaned to remove any undesirable materials left on the surfaces 204 or 206 of the substrate after step 509, as shown in FIG. 4F. For example, surface oxides or surface glass-type material may be removed. The substrate 202 may be cleaned using a wet cleaning process in which it is sprayed with a cleaning solution. The cleaning solution may be any conventional cleaning solution, such as HF-last type cleaning solution, ozonated water cleaning solution, hydrofluoric acid (HF) and hydrogen peroxide (H₂O₂) solution, or other suitable cleaning solution. The cleaning process may be performed on the substrate 202 for between about 5 seconds and about 600 seconds, such as about 120 seconds.

### Passivation and Metallization Processing Sequence Steps

At step 513, an antireflection layer (antireflective coating or ARC) or passivation layer 218 is formed on the front textured surface 208 of the substrate 202, as shown in FIGS. 4G or 4K. The passivation/ARC layer 218 may optionally include a transparent conductive oxide (TCO) layer (not shown) as needed. In one example, the passivation/ARC layer 218 may be a thin passivation/ARC layer, such as silicon oxide (SiOₓ), magnesium fluoride (MgF₂), titanium oxide (TiOₓ), aluminum oxide (AlₓO_{y}) or silicon nitride (SiNₓ) layer. In one example, the passivation/ARC layer 218 includes an aluminum oxide (AlₓO_{y}) layer that is formed by atomic layer deposition (ALD), chemical vapor deposition (CVD), physical vapor deposition (PVD) or plasma enhanced chemical vapor deposition (PECVD). This layer may be between about 50 Angstroms (Å) and about 350 Å thick, such as 150 Å thick, to effectively passivate the substrate surface.

In another embodiment, the passivation/ARC layer 218 may be a film stack that may comprise a first layer that is in contact with the front textured surface 208 and a second layer that is disposed on the first layer. In one example, the first layer may comprise a silicon nitride layer formed by a plasma enhanced chemical vapor deposition (PECVD) process that is between about 50 Angstroms (Å) and about 350 Å thick, such as 150 Å thick, and has a desirable quantity (Q₁) of trapped charge formed therein, to effectively passivate the substrate surface. In one example, the second layer may comprise a silicon nitride (SiN) layer formed by a PECVD process that is between about 400 Å and about 700 Å thick, such as 600 Å thick, which may have a desirable quantity (Q₂) of trapped charge formed therein, to effectively help bulk passivate the substrate surface. One will note that the type of charge, such as a positive or negative net charge based on the sum of Q₁ and Q₂, is preferentially set by the type of substrate over which the passivation layers are formed. However, in one example, a total net positive charge of between about 8×10⁻⁸ Coulombs/cm² to about 1.6×10⁻⁶ Coulombs/cm² is desirably achieved over an n-type substrate surface, whereas a total net negative charge of between about 8×10⁻⁸ Coulombs/cm² to about 1.6×10⁻⁶ Coulombs/cm² would desirably be achieved over a p-type substrate surface. In other words, a passivation/ARC layer 218 may have a total net positive or negative charge density within a range of 5×10¹¹/cm² to about 1×10¹³ /cm². Alternately, in certain embodiments where a heterojunction type solar cell is desired, the passivation/ARC layer 218 may include a thin (20-100 Å) intrinsic amorphous silicon (i-a-Si:H) layer followed by an ARC layer (e.g., silicon nitride), which can be deposited using a physical vapor deposition (PVD) process or a chemical vapor deposition (CVD) process.

At step 514, a back side passivation layer 220 is deposited on the second surface 206 (e.g., back surface) of the substrate 202, as shown in FIG. 4H or 4L. The passivation layer 220 may be a dielectric layer providing good interface properties that reduce the recombination of the electrons and holes, and drive and/or diffuse electrons and charge carriers back to the p-n junction. In one embodiment, the passivation layer 220 may be fabricated from a dielectric material selected from a group consisting of silicon nitride hydride (SiₓN_{y}:H), silicon oxide (SiOₓ), titanium oxide (TiOₓ), aluminum oxide (AlₓO_{y}), silicon nitride (SiNₓ), silicon oxynitride (SiOₓN_{y}), a composite film of silicon oxide and silicon nitride, a tantalum oxide layer (TaₓO_{y}), or any other suitable materials. In one embodiment, the passivation layer 220 utilized herein is an aluminum oxide layer (AlₓO_{y}). The aluminum oxide layer (AlₓO_{y}) may be formed by any suitable deposition technique, such as atomic layer deposition (ALD), plasma enhanced chemical vapor deposition (PECVD), metal-organic chemical vapor deposition (MOCVD), physical vapor deposition (PVD) or the like. In an exemplary embodiment, the passivation layer 220 is an aluminum oxide layer (AlₓO_{y}) formed by a MOCVD or ALD process having a thickness between about 5 nm and about 120 nm. In another exemplary embodiment, the passivation layer 220 is a single thin silicon oxide (SiO₂) layer with a net positive or negative charge density less than 3.2×10⁻⁸ Coulombs/cm². In other words, the passivation layer 220 is a single thin silicon oxide (SiO₂) layer with a net (electron or hole) charge density of less than 2×10¹¹/cm². In one embodiment, the passivation layer 220 is a dual layer dielectric stack of silicon oxide and silicon nitride (SiOₓ/SiN_{y}). In another embodiment, the passivation layer 220 is a dual layer dielectric stack of aluminum oxide and silicon nitride (AlOₓ/SiN_{y}). In yet another embodiment, the passivation layer 220 is a dual layer dielectric stack of silicon oxynitride and silicon nitride (SiOₓN_{y}/SiN_{z}). A further example of a passivation layer 220 stack is a stack of aluminum oxide and silicon oxynitride (AlOₓ/SiO_{y}N_{z}).

At step 516, as depicted in FIG. 4M or 4P, a patterned metal paste layer, for forming the rear contact structure 222 illustrated in FIG. 2D, is selectively deposited on the passivation layer 220 to form a back or rear paste structure 221 by use of an ink jet printing, rubber stamping, stencil printing, screen printing, or other similar process. In one embodiment, the rear paste structure 221 is disposed in a desirable pattern on the passivation layer 220 by a screen printing process in which the rear paste structure 221 is printed on passivation layer 220 through a stainless steel screen. In one example, the screen printing process may be performed in a SoftLine™ system available from Applied Materials Italia S.r.I., which is a division of Applied Materials Inc. of Santa Clara, Calif. It is also contemplated that deposition equipment from other manufactures may also be utilized.

The formed rear paste structure 221 may include polymer resin having metal particles disposed therein. The polymer and particle mixture is commonly known as “pastes” or “inks”. The polymer resins act as a carrier to help enable printing of the rear paste structure 221 onto the passivation layer 220. Other organic chemicals are added to tune the viscosity, surface wetting, or other properties of the paste. The polymer resin and other organics are removed from the passivation layer 220 or from the substrate 202 during the subsequent firing process, which will be discussed further detail below. Glass frits may also be included in the rear paste structure 221. Chemical compounds contained in the glass frits found in the rear paste structure 221 will react with the passivation layer 220 materials disposed on the substrate 202 to allow the metallic elements, and other components of the paste, to diffuse (e.g., firing through) into the passivation layer 220 and form a rear contact structure 222 with the substrate 202, as well as facilitating coalescence of the metal particles in the paste and passivation layer to form a conductive path through the passivation layer 220. Glass frits thus enable the rear paste structure 221 to pattern the passivation layer 220, thus allowing the metal particles in the passivation layer 220 to form electrical contacts through the passivation layer 220. In one embodiment, metal particles found in the rear paste structure 221 may comprise a material selected from the group consisting of silver, silver alloy, copper (Cu), tin (Sn), cobalt (Co), rhenium (Rh), nickel (Ni), zinc (Zn), lead (Pb), and/or aluminum (Al), or other suitable metals to provide a proper conductive source for forming electrical contacts to the substrate surface through the passivation layer 220. Additional components in the back contact metal paste are generally selected so as to promote effective “wetting” of the passivation layer 220 while minimizing the amount of spreading that can affect the formed feature/contact metal patterns in the passivation layer 220.

In one embodiment, the rear paste structure 221 includes aluminum (Al) particles disposed in a polymer resin that is used to form electrical contacts and back-surface-field (BSF) regions on the rear surface of a p-type substrate. In some configurations, the aluminum paste may also include aluminum particles and a glass frit disposed therein to form aluminum metal contacts through the passivation layer 220. In one embodiment, the aluminum paste is selected to facilitate the low temperature dissolution of aluminum oxide, found in the passivation layer 220, and the formation of aluminum silicon alloys during a subsequent metal contact co-firing process, which will be discussed below in detail. In some configurations, the aluminum paste includes aluminum and bismuth silicides, bismuth germinate, sodium hexafluoroaluminate (cryolite) or other chlorine or fluorine containing compounds that bond with aluminum to form a chemically active material that can fire-through the passivation layer 220 (e.g., aluminum oxide) and form an aluminum silicon alloy with regions of the p-type substrate 202 during a subsequent metal contact co-firing process. In one example, the formed pattern of metal paste features disposed on the passivation layer 220 includes an aluminum paste that is disposed over an aluminum oxide passivation layer disposed on the rear surface 206 of the p-type substrate 202, wherein the patterned metal paste comprises an array of fingers to form an array of conducting fingers 222B (FIG. 2D) that are between about 30 μm and about 200 pm wide and between about 5 and 30 μm thick over an aluminum oxide passivation layer that is between about 5 and 100 nm thick. In general, the conductive busbar 222A, similarly formed from the rear paste structure 221, of the rear contact structures 222 (FIG. 2C) is formed and attached to at least a portion of the fingers 222B to allow the solar cell device to be connected to other solar cells or external devices. The conductive busbar 222A may be between about 200 μm and about 4000 μm wide and between about 5 and 30 μm thick. As noted above, in one example, the methods described herein can reduce the amount of metal paste used on the rear surface of the substrate by between about 60% and about 99.6% over a blanket deposited metal paste layer that is formed in a conventional solar cell device. One skilled in the art will also appreciate that the metal paste materials used herein will generally be significantly less expensive than the common metal pastes used in the industry that are specifically tailored to not “fire-through”, or react with, the passivation layer materials they are disposed over.

At step 518, metallization layers, such as front metallic paste structure 225, are formed on the passivation/ARC layer 218 on the textured surface 208 of the substrate 202, as shown in FIG. 4N or 4Q. A front metallic paste structure 225 may be formed in a desirable pattern on the surface of the passivation/ARC layer 218 after the rear paste structure 221 is disposed on the back surface 206 of the substrate 202. In some embodiments, vias may be formed through the passivation/ARC layer 218 by use of an etching or ablation process so that portions of the formed front contact structures 226 (formed from paste structure 225) can form good electrical contacts with the exposed portions of the doped region 213 formed on the front surface 204 of the substrate 202. In another embodiment, a front metal paste structure 225 can be printed similarly to the rear paste structure 221 described above. The front and rear pastes may contain exactly the same mixture of metal powers and other ingredients such as glass frits. Alternately, the front and rear pastes may be formulated differently for providing dielectric layer-specific or contact-specific properties. In a one embodiment, the front and rear sides are printed with patterns of paste which are both co-fired or sintered simultaneously to form conducting contacts. By using only one co-firing process step, and by eliminating any requirements for selective etching or lithographic patterning techniques, solar cell manufacturing costs can be reduced. In general, the front contact structures 226 may be between about 500 angstroms and about 10 μm thick, about 10 μm to about 200 μm wide, and contain a metal, such as aluminum (Al), silver (Ag), tin (Sn), cobalt (Co), rhenium (Rh), nickel (Ni), zinc (Zn), lead (Pb), palladium (Pd), molybdenum (Mo), titanium (Ti), vanadium (V), tungsten (W), or chromium (Cr). In one example, the front conductive contact paste 225 is a metallic paste that contains silver (Ag) and is deposited in a desired pattern by a screen printing process. The screen printing process may be performed by a Softline™ system available from Applied Materials Italia S.r.I., a division of Applied Materials, Inc. of Santa Clara, Calif.

In general, the conductive busbar 226A (FIG. 2C) is formed and attached to at least a portion of the fingers 226B of the front contact structure 226 to allow the solar cell device to be connected to other solar cells or external devices. In one embodiment, the conductive busbar 226A is about 200 microns thick and contains a metal, such as aluminum (Al), copper (Cu), silver (Ag), gold (Au), tin (Sn), cobalt (Co), rhenium (Rh), nickel (Ni), zinc (Zn), lead (Pb), palladium (Pd), and/or aluminum (Al). In one embodiment, each of the conductive busbars 226A are formed from a wire that is about 30 gauge (AWG: ˜0.254 mm) or smaller in size.

At step 520, after the rear paste structure 221 and the front paste structures 225 are formed, a thermal processing step (e.g., a co-firing process or called a “co-fire-through” metallization process) is performed to simultaneously transform (densify and/or sinter) the rear paste structure 221 into the rear contact structure 222, while transforming (densifying and/or sintering) the front paste structure 225 into the front contact structure 226. During this thermal processing step 520, the rear paste structure 221 chemically decomposes and/or etches and “fires through” the passivation layer 220 to form good electrical contacts 232 with the back surface 206 of the substrate 202, as shown in FIG. 4O or 4R. Also during step 520, portions of the passivation/ARC layer 218 are chemically decomposed and/or etched through, and the front contact paste structures 225 “fires through” the front side passivation layer 218 to form front side electrical contact regions 231. After performing step 520, the regions of the patterned rear contact structure 222 form a conductive path that is in electrical contact with the rear surface contact region 232 and extend through the passivation layer 220 so that these formed regions of patterned metal contacts can be subsequently connected together to form a back surface contact structure. Similarly, after performing step 520, the regions of the front contact structures 226, which include the fingers 226B and the bus-line 226A, form a conductive path that is in electrical contact with the front surface contact regions 231 and extend through the passivation layer 218 to form a front side contact structure. In one embodiment, the peak firing temperature may be controlled between about 600 degrees Celsius and about 900 degrees Celsius, such as about 800 degrees Celsius for short time period, such as between about 1 seconds and about 8 seconds, for example, about 2 seconds. The firing process will also assist in evaporating the polymer or etchant materials found in the rear contact structure 222 and the front contact structures 226.

It is generally desirable for step 520 to be performed using a thermal process that is similar to a conventional front contact “firing” process to assure that the conventional front side metallization processes will not be affected by the addition of the back side contact formation during this “co-firing” step. To assure that the patterned rear contact structure 222 will “fire-through” the passivation layer 220 during step 520, the thickness of the passivation layer 220, the passivation layer composition, the composition of the metal paste material and the mass of each of the patterned back contact metal paste may need to be adjusted to assure that a repeatable solar cell device formation process is achieved.

It is noted that steps 516 to 520, as indicated in the dotted line box 550, and the embodiments of the devices structures illustrated in FIGS. 4H to 4K, as indicated in the dotted line box 550, may be replaced with a different set of process steps/process sequences to possibly enhance portions of the solar cell manufacturing process and/or form different solar cell structures as needed to meet different device performance requirements or process need.

### Contact Structure Enhancement Processes

Some of the embodiments of the processing sequence 500, as illustrated in FIG. 5B, include a contact structure enhancement process 530 that is used to prepare the rear contact structure 222 and/or the front contact structure 226 of a bifacial solar cell 200 for electrical connection to other solar cells in a solar cell module and/or an external load. In one configuration, the prepared rear contact structure 222 and front contact structure 226 enable a good electrical connection to be formed with the connecting elements used in a stringing process, which is used to interconnect multiple solar cells in a module together. The contact structure enhancement process 530 may include a contact preparation process 532, an optional cleaning process 534 and a bonding material deposition process 536.

In one embodiment, the contact structure preparation process 532 includes a process of etching, abrading, and/or performing some mechanical or chemical preparation process that is able to remove any exposed oxides or other contaminants found on formed metallic surfaces 222S or 226S (FIG. 4S) of the rear contact structure 222 and/or the front contact structure 226, and remove any partially sintered metallic material found in the rear contact structure 222 or front contact structure 226, so that a good ohmic contact can be made to the solar cell 200 during the subsequent module fabrication process. In one embodiment, the contact structure preparation process 532 includes abrading the material used to form the rear contact structure 222 (e.g., sintered aluminum paste) and/or the front contact structure 226 (e.g., sintered silver paste) with an abrading material that has a Mohs hardness greater than the material used to form the rear contact structure 222 and the front contact structure 226. In one example, the contact structure preparation process 532 includes abrading the material used to form the rear contact structure 222 and/or the front contact structure 226 using a grit blasting process that is only applied to desired regions, or surfaces 222S and 226S, of the formed interconnect structures by use of masking components.

At step 534, one or more portions of the rear contact structure 222 and/or the front contact structure 226 are optionally cleaned to remove any undesirable materials left thereon after performing step 532. The one or more portions of the rear contact structure 222 and/or the front contact structure 226 may be cleaned using a wet cleaning process such as an ultrasonic or megasonic rinse, mechanical polishing, a blow drying process, super critical CO₂ cleaning process, wiping the surface with a cloth or other useful cleaning process.

At step 536, a conductive layer 247 (FIG. 4T) may be formed over the regions on which the processes performed in steps 532-534 were applied to form a desirable region that can be easily electrically connected to in a subsequent processing step. In one embodiment, the processes at step 536 include depositing a conductive layer 247, also referred to herein as a bonding material, on the regions on which the processes performed in steps 532-534 were applied. The bonding material is chosen, such that it can make a conductive and chemically, galvanically, and mechanically stable contact to one or more of the layers in contact region of the solar cell (e.g., AlOₓ, Al, AlSi_{y}, Si). Examples of bonding materials are alloys containing one or more of the following elements Pb, Sn, Ag, Bi, In, Sb, Ti, Mg, Ga, Ce or other metals. The metals are chosen to balance the chemical oxidation resistance of the aluminum film, ductility and brittleness of the soldered contact, stress of the soldered contact, conductivity of the contact, and cost of the solder. The method of depositing and activating the solder can be inductive (thermal), ultrasonic, laser, microwave, plasma, or any combination of these techniques. In one embodiment, the bonding material is connected to external contact structures using a metal conductor material that may contain a solder material (e.g., Sn/Pb, Sn/Ag). In one embodiment, the busbar 226A or busbar 222A is coated with a solder material, such as a Sn/Pb or other useful solder material.

Therefore, using the processes and materials described herein, the front and back contact structures of a bifacial solar cell may be simultaneously formed in one step, thereby advantageously reducing the need for additional thermal processing steps and eliminating the need to etch passivation layers, due to the use of a fire-through metallization process, thus, saving and reducing manufacture cost, cycle time and throughput. In addition, by depositing a simple patterned metallic conductive regions in the back structure, and use of a low cost interconnection layer to connect the patterned back contact regions together and as a light reflector on the back of the substrate, the light collection of the solar cell devices may also be increased, which further reduces the per-Watt cost of solar cell device production.

While the foregoing is directed to embodiments of the present invention, other and further embodiments of the invention may be devised without departing from the basic scope thereof, and the scope thereof is determined by the claims that follow.

What is claimed is:

1. A method of manufacturing a solar cell device, comprising:
forming a doped region on a first surface of a substrate;
forming a first dielectric layer on the first surface of the substrate;
forming a second dielectric layer on a second surface of the substrate;
depositing a first metal paste in a first pattern on at least a portion of the first dielectric layer;
depositing a second metal paste in a second pattern on the second dielectric layer, wherein the second dielectric layer is disposed between the portions of the second metal paste and the second surface of the substrate, and the second metal paste comprises aluminum; and
simultaneously heating the first and the second metal pastes disposed on the first and the second dielectric layers to form a first group of contacts to the substrate through portions of the first dielectric layer and a second group of contacts to the substrate through the second dielectric layer, wherein at least a portion of the second metal paste forms a plurality of contact regions that each extend through the second dielectric layer from the surface of the second dielectric layer to the second side of the substrate.

2. The method of claim 1, wherein the second dielectric layer comprises aluminum oxide.

3. The method of claim 2, wherein the first dielectric layer is a dielectric layer selected from a group consisting of silicon oxide layer, silicon nitride layer, silicon oxynitride layer or combinations thereof.

4. The method of claim 2, wherein the second dielectric layer is a dielectric layer selected from a group consisting of aluminum oxide (AlOₓ), silicon oxynitride (SiOₓN_{y}), silicon dioxide (SiO₂), silicon oxide (SiOₓ), silicon nitride (SiNₓ), or combinations thereof.

5. The method of claim 1, wherein the second dielectric layer comprises an aluminum oxide layer and a silicon nitride layer, wherein the silicon nitride layer is disposed on the aluminum oxide layer, and the aluminum oxide layer is disposed on the second surface which is textured.

6. The method of claim 1, wherein the substrate comprises a p-type doped substrate.

7. The method of claim 1, wherein the first pattern and the second pattern have the same geometric structure.

8. A bifacial solar cell device, comprising:
a substrate having a first dielectric layer disposed on a first side of the substrate and a second dielectric layer disposed on a second side of the substrate, wherein the first side of the substrate includes a textured surface;
a first metal layer that is formed in a first pattern on the first side of the substrate; and
a second metal layer that is formed in a second pattern on the second side of the substrate, wherein the second metal comprises aluminum and the second dielectric layer comprises aluminum oxide.

9. The bifacial solar cell device of claim 8, wherein the area of the second surface of the substrate that is not covered by the second metal layer is between about 90% and about 70% of the area.

10. The bifacial solar cell device of claim 8, wherein the second side of the substrate includes a textured surface.

11. The bifacial solar cell device of claim 8, wherein the first metal layer comprises silver, and the first metal layer and the second metal layer both further comprise an element selected from the group consisting of Pb, Sn, Ag, Bi, In, Sb, Ti, Mg, Ga and Ce.

12. The bifacial solar cell device of claim 8, wherein the first dielectric layer comprises silicon oxide (SiOₓ), magnesium fluoride (MgF₂), titanium oxide (TiOₓ), aluminum oxide (AlₓO_{y}) or silicon nitride (SiNₓ).

13. The bifacial solar cell device of claim 8, wherein the substrate comprises n-doped silicon and the second metal comprises aluminum, and the bifacial solar cell device further comprises an n⁺-doped layer disposed between the substrate and the first dielectric layer.

14. The bifacial solar cell device of claim 8, further comprising a layer of transparent conducting metal oxide disposed over the first dielectric layer.

15. A method of forming a solar cell, comprising:
printing a first pattern of a first metallic paste onto a first dielectric layer disposed over a surface of a solar cell substrate, wherein the first metallic paste comprises a first metal powder;
printing a second pattern of a second metallic paste onto a second dielectric layer disposed over a surface of the solar cell substrate, wherein the second metallic paste comprises a second metal powder; and
co-firing the patterns of first and second metallic pastes, wherein co-firing the patterns of first and second metallic pastes causes densification of the first and second metal powders.

16. The method of claim 15, wherein the first metal powder comprises silver (Ag) and the first metal powder comprises aluminum (Al).

17. The method of claim 16, wherein the first dielectric layer comprises aluminum and oxygen, and the second dielectric layer comprises silicon and nitrogen.

18. The method of claim 17, wherein the semiconductor substrate is a p-type silicon substrate.

19. The method of claim 17, wherein the semiconductor substrate is an n-type silicon substrate.

20. The method of claim 15, wherein the first dielectric layer and the second dielectric layer are disposed on opposite sides of the solar cell substrate.
